(19) United States
(12) Patent Application Publication
(10) Pub. No.: US 2015/0279671 A1
(43) Pub. Date: Oct. 1, 2015

(54) METHOD FOR FORMING OXIDE THIN FILM AND METHOD FOR FABRICATING OXIDE THIN FILM TRANSISTOR EMPLOYING GERMANIUM DOPING

(71) Applicant: Industry-Academic Cooperation Foundation, Yonsei University, Seoul (KR)

(72) Inventors: Hyun Jae Kim, Seoul (KR); Chul Ho Kim, Gyeonggi-do (KR); Si Joon Kim, Seoul (KR); Tae Soo Jung, Seoul (KR)

(21) Appl. No.: 14/659,722

(22) Filed: Mar. 17, 2015

(30) Foreign Application Priority Data
Mar. 28, 2014 (KR) 10-2014-0037087

(51) Int. Cl. H01L 21/02; H01L 29/66

(52) U.S. Cl. CPC H01L 21/02565; H01L 21/02664; H01L 21/02628; H01L 29/66969

(57) ABSTRACT

The present invention disclosed herein relates to a method for forming an oxide film and a method for fabricating an oxide thin film transistor, and more particularly, to a method for forming an oxide film and a method for fabricating an oxide thin film transistor which employ a germanium doping. A method for forming an oxide thin film according to an embodiment of the present invention, the method includes: applying a metal compound on a substrate; and heat-treating the substrate, wherein the metal compound solution is prepared by dissolving an indium compound, a zinc compound and a germanium compound in a solvent.

### CROSS-REFERENCE TO RELATED APPLICATIONS

This U.S. non-provisional patent application claims priority under 35 U.S.C. §119 of Korean Patent Application No. 10-2014-0037087, filed on Mar. 28, 2014, the entire contents of which are hereby incorporated by reference.

### BACKGROUND OF THE INVENTION

The present invention disclosed herein relates to a method for forming an oxide film and a method for fabricating an oxide thin film transistor, and more particularly, to a method for forming an oxide film and a method for fabricating an oxide thin film transistor which employ a germanium doping.

Recently, studies on an oxide semiconductor device replacing a Si-based semiconductor device have been conducted. The oxide semiconductor device is a semiconductor device that includes a thin film formed of a metal oxide, and has excellent electrical and optical characteristics compared to the Si-based semiconductor device to receive attention as a switching device for a display panel.

Materials forming a metal oxide thin film of the oxide semiconductor device are mostly currently restricted to some metals such as indium, gallium, zinc, tin, and the like. In order to improve characteristics of oxide thin films based on the foregoing metals, studies are conducted to employ separate processes such as a post-treatment or the like.

### SUMMARY OF THE INVENTION

The present invention provides a method for forming an oxide thin film and a method for fabricating an oxide thin film transistor in which instead of a separate post-treating process being introduced, a new material is included in an oxide thin film, thereby improving characteristics of the thin film.

The present invention also provides a method for forming an oxide thin film and a method for fabricating an oxide thin film transistor in which when an oxide thin film is formed, a heat-treating temperature is lowered to prevent a substrate from being deformed due to a high temperature.

Embodiments of the present invention provide methods for forming an oxide thin film, the methods including: applying a metal compound solution on a substrate; and heat-treating the substrate, wherein the metal compound solution is prepared by dissolving an indium compound, a zinc compound and a germanium compound in a solvent.

In some embodiments, a molar ratio between the indium compound and the zinc compound may be in a range of about 1:5 to about 5:1.

In other embodiments, a molar ratio between the indium compound and the zinc compound may be about 5:1.

In still other embodiments, the molar percentage of the germanium compound with respect to the zinc compound and the germanium compound may be greater than about 0% and be about 15% or less.

In even other embodiments, the molar percentage of the germanium compound with respect to the indium compound, the zinc compound, and the germanium compound is about 4.3%.

In yet other embodiments, the metal compound solution may include at least one of a nitric acid, an acetic acid, a hydrochloric acid, a sulfuric acid, and monoethanolamine which are added therein.

In further embodiments, the metal compound solution may include the nitric acid added therein.

In still further embodiments, a molar ratio between the solvent and the nitric acid is about 20:1.

In even further embodiments, the heat-treating of the substrate may include heat-treating the substrate in a temperature range of about 240° C. to about 280° C.

In yet further embodiments, the heat-treating of the substrate may further include heat-treating the substrate in a temperature range of about 100° C. to about 150° C. prior to heat-treating the substrate in a temperature range of about 240° C. to about 280° C.

In much further embodiments, the heat-treating of the substrate in the temperature range of about 100° C. to about 150° C. may include heat-treating the substrate at a temperature of about 135° C.

In still much further embodiments, the heat-treating of the substrate at the temperature of about 135° C. may include heat-treating the substrate at a temperature of about 135° C. for about 5 minutes; and the heat-treating of the substrate in the temperature range of about 240° C. to about 280° C. may include heat-treating the substrate in a temperature range of about 240° C. to about 280° C. for about 4 hours.

In other embodiments of the present invention, methods for fabricating an oxide thin film transistor, the methods including: forming a gate and an insulation layer on a substrate; applying a metal compound solution on the insulation layer; heat-treating the substrate to form an oxide thin film from the metal compound solution; and forming a source and a drain on the oxide thin film, wherein the metal compound solution is prepared by dissolving an indium compound, a zinc compound, and a germanium compound in a solvent.

In some embodiments, a molar ratio between the indium compound and the zinc compound may be in a range of about 1:5 to about 5:1.

In other embodiments, a molar ratio between the indium compound and the zinc compound may be about 5:1.

In still other embodiments, a molar percentage of the germanium compound with respect to the zinc compound and the germanium compound may be greater than about 0% and be about 15% or less.

In even other embodiments, the molar percentage of the germanium compound with respect to the indium compound, the zinc compound, and the germanium compound may be about 4.3%.

In yet other embodiments, the metal compound solution may include at least one of a nitric acid, an acetic acid, a hydrochloric acid, a sulfuric acid, and monoethanolamine which are added therein.

In further embodiments, the metal compound solution may include the nitric acid added therein.

In still further embodiments, a molar ratio between the solvent and the nitric acid may be about 20:1.

In even further embodiments, the heat-treating of the substrate to form the oxide thin film from the metal compound solution may include: pre-heat treating the substrate in a temperature range of about 100° C. to about 150° C.; and post-heat treating the substrate in a temperature range of about 240° C. to about 280° C.

In yet further embodiments, the pre-heat treating of the substrate in the temperature range of about 100° C. to about 150° C. may include pre-heat treating the substrate at a temperature of about 135° C. for about 5 minutes.

In much further embodiments, the post-heat treating of the substrate in the temperature range of about 240° C. to about 280° C. may include post-heat treating the substrate in the temperature range of about 240° C. to about 280° C. for about 4 hours.

In still other embodiments of the present invention, methods for fabricating an oxide thin film transistor, the methods including: forming an insulation layer on a substrate; applying a metal compound solution on the insulation layer; pre-heat treating the substrate at a temperature of about 135° C. for about 5 minutes; post-heat treating the substrate in a temperature range of about 240° C. to about 280° C. for about 4 hours to form an oxide thin film from the metal compound solution; and forming a source and a drain on the oxide thin film, wherein the metal compound solution includes at least one of a nitric acid, an acetic acid, a hydrochloric acid, a sulfuric acid, and monoethanolamine which are added therein; the molar ratio between the indium compound and the zinc compound is about 5:1; the molar percentage of the germanium compound with respect to the indium compound, the zinc compound, and the germanium compound is about 4.3%; the metal compound solution includes a nitric acid added therein; and the molar ratio between the solvent and the nitric acid is about 20:1.

### BRIEF DESCRIPTION OF THE DRAWINGS

The accompanying drawings are included to provide a further understanding of the present invention, and are incorporated in and constitute a part of this specification. The drawings illustrate exemplary embodiments of the present invention and, together with the description, serve to explain principles of the present invention. In the drawings:

FIG. 1 is an exemplary flow chart showing a method for forming an oxide thin film according to an embodiment of the present invention;

FIG. 2 is an exemplary flow chart showing a method for fabricating an oxide thin film transistor according to an embodiment of the present invention;

FIGS. 3 to 7 are exemplary views illustrating processes for fabricating an oxide thin film according to an embodiment of the present invention;

FIG. 8 is a graph showing a carrier concentration, hole mobility, and resistivity of an oxide thin film according to a germanium content;

FIG. 9 is a graph showing transfer characteristics of an InZnO thin film transistor heat-treated at a temperature of about 280° C., and germanium-doped InZnO thin film transistors heat-treated at temperatures of about 280° C., about 260° C. and about 240° C.;

FIG. 10 is a graph showing transfer characteristic of germanium-doped InZnO thin film transistor having germanium content of 6.34% and heat-treated at a temperature of about 280° C.;

FIG. 11 is a graph showing PBS test results of an InZnO thin film transistor heat-treated at a temperature of about 280° C.;

FIG. 12 is a graph showing PBS test results of a germanium-doped InZnO thin film transistor heat-treated at a temperature of about 280° C.;

FIG. 13 is a graph showing PBS test results of a germanium-doped InZnO thin film transistor heat-treated at a temperature of about 250° C.;

FIG. 14 is a graph showing PBS test results of a germanium-doped InZnO thin film transistor heat-treated at a temperature of about 240° C.; and

FIG. 15 is a graph showing variations of threshold voltage according to time, obtained from PBS tests of an InZnO thin film transistor heat-treated at a temperature of about 280° C., and germanium-doped InZnO thin film transistors heat-treated at temperatures of about 280° C., about 260° C. and about 240° C.

### DETAILED DESCRIPTION OF PREFERRED EMBODIMENTS

Hereinafter, embodiments of the present invention will be described in detail with reference to the accompanying drawings.

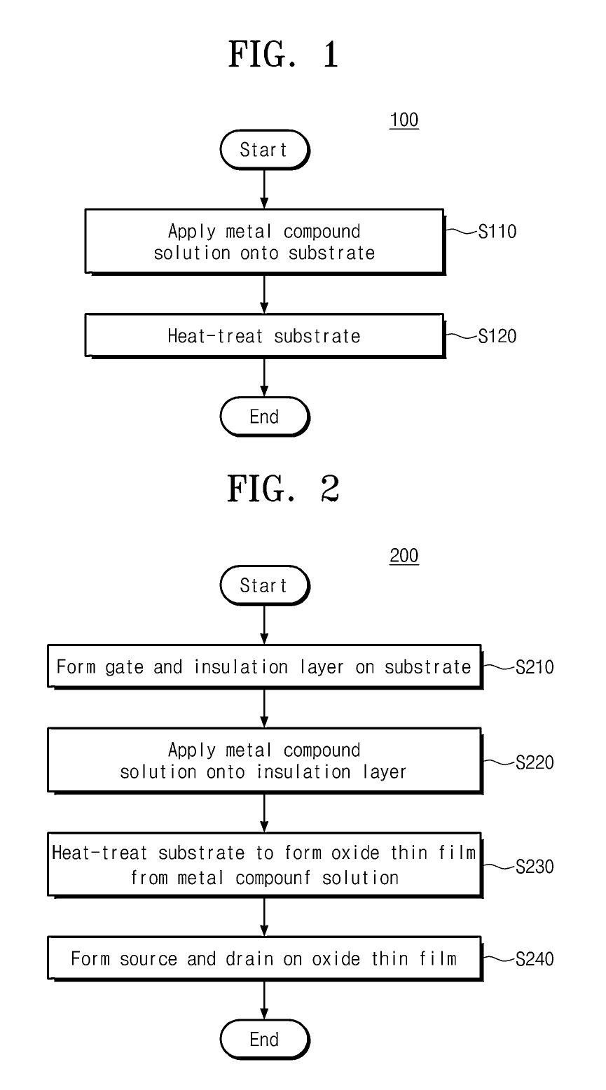

FIG. 1 is an exemplary flow chart showing a method 100 for forming an oxide thin film according to an embodiment of the present invention.

As shown in FIG. 1, the method 100 for forming the oxide thin film includes applying a metal compound solution on a substrate (S110) and heat-treating the substrate (S120). That is, the method 100 for forming the oxide thin film according to an embodiment of the present invention is based on a solution process.

According to an embodiment of the present invention, the metal compound solution further includes a germanium precursor in addition to precursors of metals forming the oxide thin film.

According to an embodiment, the oxide thin film may be formed of at least one material of InZnO, ZnO, InGaZnO, InGaZnO₄, ZrInZnO, AlInZnO, ZnSnO, ZnSnO₃, ZnSnO₄, In₂O₃, Ga₂O₃, HfInZnO, HfO₂, SnO₂, WO₃, TiO₂, Ta₂O₅, In₂O₃SnO₂, MgZnO, CdZnO, CuAlO₂, CuGaO₂, Nb₂O₅, and TiSrO₃, which are doped with germanium, but materials forming the oxide thin film are not limited to the aforementioned materials, so long as germanium is doped thereinto.

Hereinafter, a germanium-doped InZnO oxide thin film will be described as an embodiment of the present invention.

In order to form the germanium-doped InZnO oxide thin film, the metal compound solution may be prepared by dissolving an indium compound, a zinc compound, and a germanium compound in a solvent.

The indium compound may include, as an indium precursor, at least one of indium chloride, indium chloride tetrahydrate, indium fluoride, indium fluoride trihydrate, indium hydroxide, indium nitrate hydrate, indium acetate hydrate, indium acetylacetonate, and indium acetate, but is not limited thereto.

The zinc compound may include, as a zinc precursor, at least one of zinc citrate dehydrate, zinc acetate, zinc acetate dehydrate, zinc acetylacetonate hydrate, zinc acrylate, zinc chloride, zinc diethyldithiocarbamate, zinc dimethyldithiocarbamate, zinc fluoride, zinc fluoride hydrate, zinc hexafluoroacetylacetonate dihydrate, zinc methacrylate, zinc nitrate hexahydrate, zinc nitrate hydrate, zinc trifluoromethanesulfonate, zinc undecylenate, zinc trifluoroacetate hydrate, zinc tetrafluoroborate hydrate, and zinc perchlorate hexahydrate, but is not limited thereto.

The germanium compound may include germanium chloride as a germanium precursor, but is not limited thereto.

The solvent in which the metal compound is dissolved, may include at least one of isopropanol, 2-methoxyethanol, dimethylformamide, ethanol, deionized water, methanol, acetylacetone, dimethylamineborane, and acetonitrile, but is not limited thereto.

The molar ratio between the indium compound and the zinc compound may be in a range of about 1:5 to about 5:1, for example, about 5:1, but the molar ratio may be changed according to electrical characteristics of the thin film.

According to an embodiment of the present invention, the molar percentage of the germanium compound with respect to the indium compound, the zinc compound, and the germanium compound may be greater than about 0% and be about 15% or less, for example, be about 4.3%, but is not limited thereto.

According to an embodiment, a predetermined additive may be added to the metal compound solution. Specially, when the metal compound solution is prepared by further adding a germanium compound to an indium compound and a zinc compound according to an embodiment of the present invention, an additive may be added to the metal compound solution for smooth dissolution of germanium in the metal compound solution.

The additive may include at least one of a nitric acid, an acetic acid, a hydrochloric acid, a sulfuric acid, and monoethanolamine, but is not limited thereto.

According to an embodiment of the present invention, a nitric acid may be added to the metal compound solution as an additive. In this case, the molar ratio between the solvent and the nitric acid may be about 20:1, but is not limited thereto. Merely, as the added amount of the additive increases, solubility of a solute increases too, but a thin film characteristic may be deteriorated.

The applying of the metal compound solution on the substrate (S110) may be performed by using a spin coating, a slit coating, an inkjet coating, a spray or a dipping, but is not limited thereto.

The heat-treating of the substrate (S120) may be performed by heat-treating the substrate at a predetermined temperature to evaporate a solvent and to decompose an organic matter, thus forming a metal oxide thin film.

According to an embodiment, the heat-treating of the substrate (S120) may include heat-treating the substrate in a temperature range of about 240° C. to about 280° C. That is, the heat-treating temperature of the substrate may be in a range of about 240° C. to about 280° C.

Also, the heat-treating of the substrate (S120) may further include heat-treating the substrate at a temperature lower than about 240° C. prior to heat-treating the substrate in the temperature range of about 240° C. to about 280° C.

For example, the heat-treating of the substrate (S120) may further include heat-treating the substrate in a temperature range of about 100° C. to about 150° C. prior to heat-treating the substrate in the temperature range of about 240° C. to about 280° C.

In an example, the heat-treating of the substrate in the temperature range of about 100° C. to about 150° C. may include heat-treating the substrate at a temperature of about 135° C., but the heat-treating temperature is not limited thereto.

According to an embodiment, the heat-treating of the substrate at the temperature of about 135° C. may include heat-treating the substrate at the temperature of 135° C. for 5 minutes. Also, the heat-treating of the substrate in the temperature range of about 240° C. to about 280° C. may include heat-treating the substrate in the temperature range of about 240° C. to about 280° C. for about 4 hours. However, the heat-treating time is not limited thereto, but may be changed according to a heat-treating temperature, a material constituting the metal oxide thin film, or the like.

FIG. 2 is an exemplary flow chart showing a method 200 for fabricating an oxide thin film transistor according to an embodiment of the present invention.

As shown in FIG. 2, the method 200 for fabricating the oxide thin film transistor may include forming a gate and an insulation layer on a substrate (S210), applying a metal compound solution on the insulation layer (S220), heat-treating the substrate to form an oxide thin film from the metal compound solution (S230), and forming a source and a drain on the oxide thin film (S240).

The method 200 for fabricating the oxide thin film transistor uses the method 100 for forming the oxide thin film according to embodiments of the present invention described above.

That is, the applying of a metal compound solution on the insulation layer (S220) and the heat-treating of the substrate to form an oxide thin film from the metal compound solution (S230) in the method 200 for fabricating the oxide thin film transistor, respectively correspond to the applying of the metal compound solution on the substrate (S110) and the heat-treating of the substrate (S120) in the method 100 for forming the oxide thin film.

The afore-mentioned method 200 for fabricating the oxide thin film transistor corresponds to a method for fabricating an inverted staggered transistor that is generally used as a TFT for a display panel.

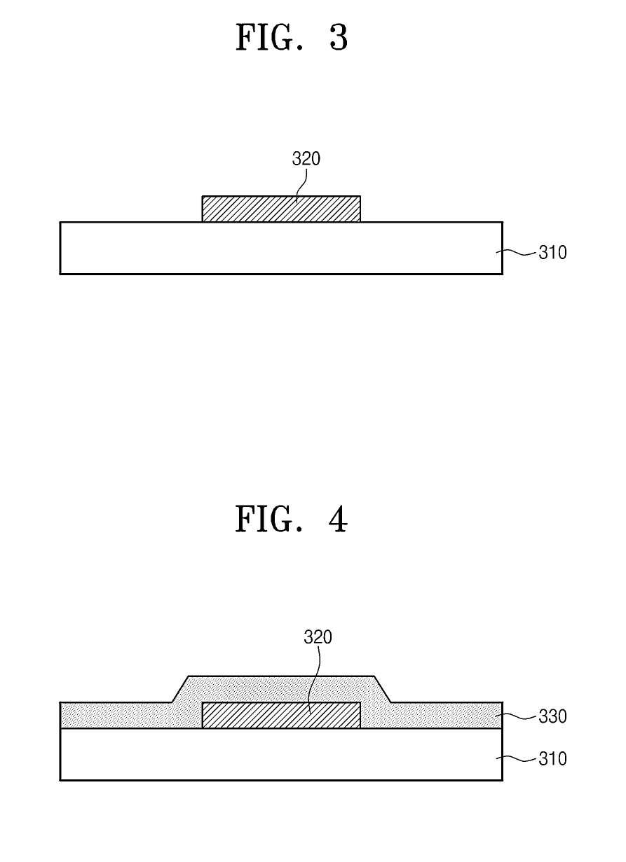

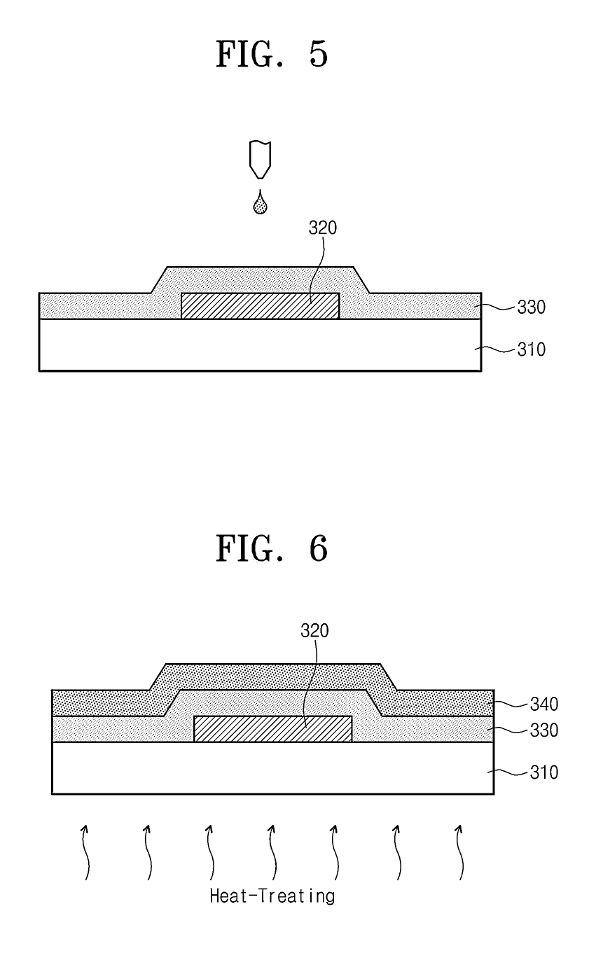

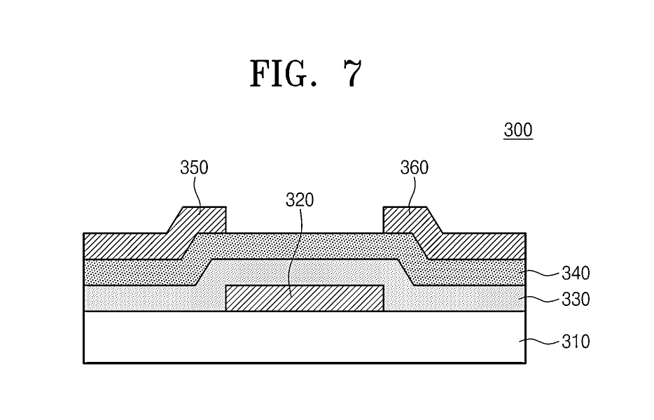

In detail, referring to FIGS. 3 to 7, in the method 200 for fabricating the oxide thin film transistor, a gate 320 is formed on a substrate 310 (see FIG. 3), an insulation layer 330 is formed on the gate 320 (see FIG. 4), and then a metal compound solution is applied on the insulation layer 330 (see FIG. 5). After that, the substrate 310 is heat-treated to form an oxide thin film 340 from the metal compound solution (see FIG. 6), and a source 350 and a drain 360 are formed on the oxide thin film 340 to fabricate an oxide thin film transistor 300 (see FIG. 7).

However, the method 200 for fabricating the oxide thin film transistor may be used to fabricate any type of transistors 300, such as a staggered type transistor, a coplanar type transistor, and an inverted coplanar type transistor in addition to an inverted staggered type transistor, so long as the transistors include an oxide thin film, by employing the method 100 for forming the oxide thin film.

Like the method 100 for forming the oxide thin film, the metal compound solution, which is used in fabricating the oxide thin film transistor 300, may be prepared by dissolving an indium compound, a zinc compound, and a germanium compound in a solvent.

According to an embodiment, the molar ratio between the indium compound and the zinc compound may be in a range of about 1:5 to about 5:1, for example, about 5:1, but is not limited thereto.

Also, the molar percentage of the germanium compound with respect to the indium compound, the zinc compound, and the germanium compound may be greater than about 0% and be about 15% or less, for example, be about 4.3%, but is not limited thereto.

A predetermined additive may be added to the metal compound solution in order to increase solubility of a solute. The additive may include at least one of a nitric acid, an acetic acid, a hydrochloric acid, a sulfuric acid and monoethanolamine

According to an embodiment of the present invention, a nitric acid may be added to the metal compound solution. In this case, the molar ratio between the solvent and the nitric acid may be about 20:1, but is not limited thereto.

According to an embodiment, the heat-treating of the substrate may be performed in two steps.

For example, the heat-treating of the substrate to form an oxide thin film from a metal compound solution (S230) may include pre-heat treating the substrate in a temperature range of about 100° C. to about 150° C., and post-heat treating the substrate in a temperature range of about 240° C. to about 280° C. .

The pre-heat treating of the substrate in the temperature range of about 100° C. to about 150° C. may include pre-heat treating the substrate at a temperature of about 135° C. for about 5 minutes, but the heat-treating temperature and the time are not limited thereto.

The post-heat treating of the substrate in the temperature range of about 240° C. to about 280° C. may include post-heat treating the substrate in a temperature range of about 240° C. to about 280° C. for about 4 hours, but the post-heat treating time is not limited thereto.

Hereinafter, operations for fabricating a thin film transistor having germanium-doped InZnO (hereinafter, referred to as Ge:InZnO) will be described.

In Embodiment of the present invention, a bottom gate thin film transistor, which has Ge:InZnO as a channel layer, was fabricated, and in Comparative Example, a bottom gate thin film transistor, which has InZnO as a channel layer, was fabricated.

A heavily boron (B)-doped p-type silicon wafer was used as a substrate to replace a gate electrode.

Also, a silicon dioxide (SiO₂) layer was grown to a thickness of about 120 nm on the substrate through a dry oxidation method to form a gate insulation layer.

Further, a metal compound solution was prepared through a solution process in order to form an oxide thin film.

In detail, indium nitrate hydrate (In(NO₃)₃.xH₂O) was used as an indium precursor, zinc nitrate hydrate (Zn(NO₃)₃.xH₂O) was used as a zinc precursor, and 2-methoxyethanol was used as a solvent. The indium precursor and the zinc precursor was dissolved at a molar ratio of about 5:1 in the solvent to prepare 0.3 M of an InZnO precursor solution.

Moreover, for use in Embodiment of the present invention, germanium chloride (GeCl₄) was further dissolved in the InZnO precursor solution as a germanium precursor. The germanium precursor was dissolved, in the solvent, at a molar percentage of about 4.3% with respect to the indium precursor, zinc precursor and germanium precursor solute to prepare a Ge:InZnO precursor solution.

A nitric acid was added to the precursor solution in order to increase solubility of the germanium precursor, and the molar ratio between the solvent and the nitric acid was about 20:1.

Next, the precursor solution was applied by using a spin coating on the substrate on which the insulation layer is formed. The spin coating was performed at a speed of about 3,000 rpm for about 30 seconds.

After that, the solution-applied substrate was heat-treated on a hot plate.

In Embodiment 1 of the present invention, the Ge:InZnO precursor solution-applied substrate was pre-heat treated at a temperature of about 135° C. of the hot plate for about 5 minutes, and then post-heat treated at a temperature of about 280° C. of the hot plate for about 4 hours to form a Ge:InZnO thin film.

Also, in Embodiments 2 to 4 of the present invention, the post-heat treatment temperatures were set to about 260° C., about 250° C. and about 240° C., respectively, and a Ge:InZnO thin film was formed through the same process as Embodiment 1 described above.

In Comparative Example, the InZnO precursor solution-applied substrate was pre-heat treated at a temperature of about 135° C. of the hot plate for about 5 minutes, and then post-heat treated at a temperature of about 280° C. of the hot plate for about 4 hours to form an InZnO thin film.

Finally, aluminum was deposited was deposited to a thickness of about 200 nm on the oxide thin film to form source and drain electrodes. At this time, a shadow mask was used to allow a channel to have a width of about 1,000 μm and a length of about 150 μm.

Electrical characteristics and stability of elements are evaluated by using the thin film transistors as fabricated above.

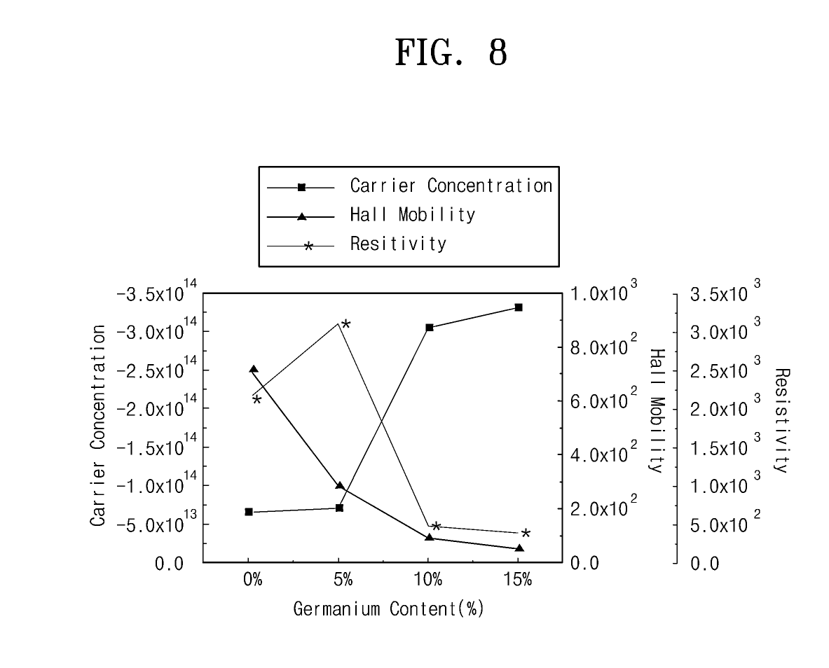

FIG. 8 is a graph showing carrier concentration, hole mobility and resistivity of an oxide thin film according to the content of germanium.

The graph shown in FIG. 8 indicates changes of carrier concentration, hole mobility and resistivity in a Ge:InZnO thin film when the germanium content (the molar percentage of germanium with respect to a total amount of solute) is changed from about 0% to about 15%. The Ge:InZnO thin film used for obtaining data shown in FIG. 8 was formed through the same process as Embodiments of the present invention described above except that post heat treatment temperature was set to about 450° C.

Referring to FIG. 8, as the germanium content is increased, the carrier concentration tends to be increased, and the hole mobility and resistivity tend to be decreased. In other words, it may be seen that as the germanium content in the thin film is increased, electrical conductivity is increased.

However, in a case that the Ge:InZnO thin film is used as a channel layer of a transistor and the electrical conductivity of the Ge:InZnO thin film is too high, an element is short-circuited, so that switching characteristics may be lost.

Accordingly, as in Embodiments of the present invention described above, when the germanium content is set to be greater than about 0% and set to about 15% or less, in detail, set to about 4 to about 5%, in more detail, set to about 4.3%, in order to fabricate a thin film transistor, it may be confirmed that characteristics of elements are excellent compared to characteristics of a thin film transistor that do not include germanium as will be explained below.

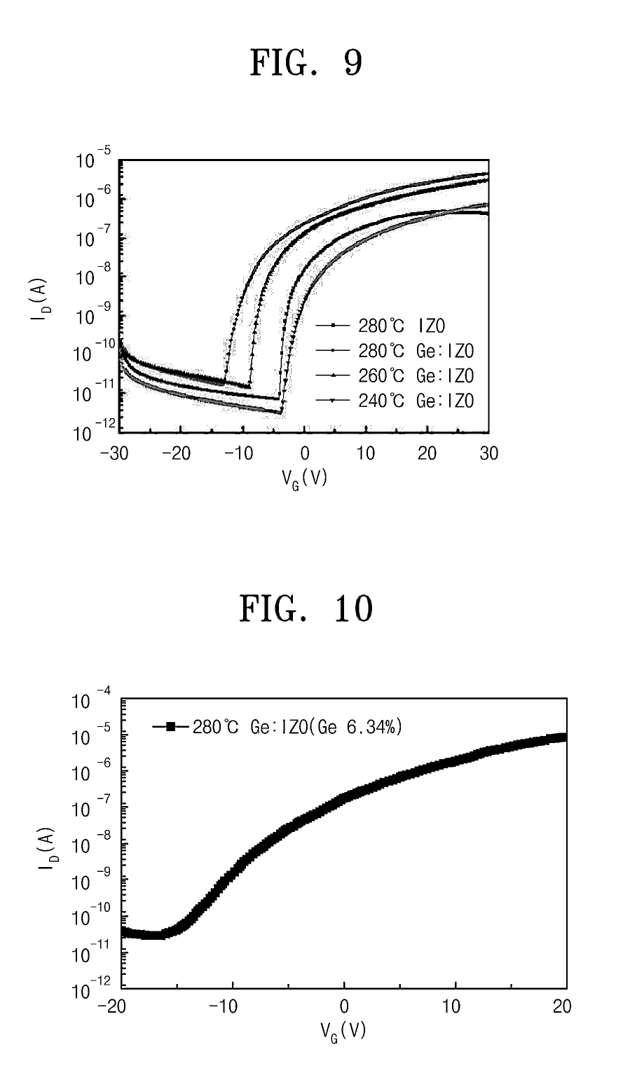

FIG. 9 is a graph showing transfer characteristics of an InZnO thin film transistor heat-treated at a temperature of about 280° C., and Ge:InZnO thin film transistors of Embodiments 1, 2 and 4 heat-treated at temperatures of about 280° C., about 260° C. and about 240° C.

Also, electron mobility, an On/Off current ratio and a subthreshold swing (SS) of each of the thin film transistors fabricated according to Comparative Example and Embodiments 1 to 4 are shown in Table 1 below.

TABLE 1

| | Post-heat treating | Electron | | |
|---|---|---|---|---|
| | temperature and thin | mobility | | S.S. |
| | film | (cm²/Vs) | Iₒₙ/I_{off} | (V/decade) |
| Comparative | 280° C. InZnO | 0.01 | 6.82 × 10⁴ | 0.77 |
| Example | | | | |
| Embodiment | 280° C. Ge:InZnO | 0.04 | 2.72 × 10⁵ | 1.2 |
| 1 | | | | |
| Embodiment | 260° C. Ge:InZnO | 0.03 | 2.10 × 10⁵ | 0.89 |
| 2 | | | | |
| Embodiment | 250° C. Ge:InZnO | 0.02 | 4.55 × 10⁴ | 0.82 |
| 3 | | | | |
| Embodiment | 240° C. Ge:InZnO | 0.01 | 3.46 × 10⁵ | 0.87 |
| 4 | | | | |

Referring to FIG. 9 and Table 1, when elements are fabricated under the same condition, it may confirmed that the elements according to Embodiments of the present invention including a thin film which is doped with germanium, are excellent in all of mobility, On/Off current ratio and subthreshold swing (SS) related to electrical characteristics compared to the element according to Comparative Example of which a thin film is not doped with germanium.

Also, when only the electron mobility having the greatest influence on electrical characteristics of an element is considered, the InZnO thin film transistor fabricated according to Comparative Example has the same performance as the Ge:InZnO thin film transistor heat-treated at a temperature of about 240° C. according to Embodiment 4 of the present invention.

Therefore, when germanium is doped into a thin film as in Embodiments of the present invention, it may be confirmed that a heat-treatment temperature of a substrate may be lowered without reducing performance of an element.

As described above, if the thin film transistor is fabricated with germanium content of about 4 to about 5%, the transistor has more excellent electrical characteristics than that of the transistor having other germanium content.

FIG. 10 is a graph showing transfer characteristic of germanium-doped InZnO thin film transistor having germanium content of 6.34% and heat-treated at a temperature of about 280° C.

Comparing the transfer curve of FIG. 10 with that of the transistor having germanium content of 4.3% and heat-treated at about 280° C. as illustrated in FIG. 9, it may be confirmed that the transistor with germanium content of about 4 to about 5% has more excellent switching characteristics than the transistor having other germanium content.

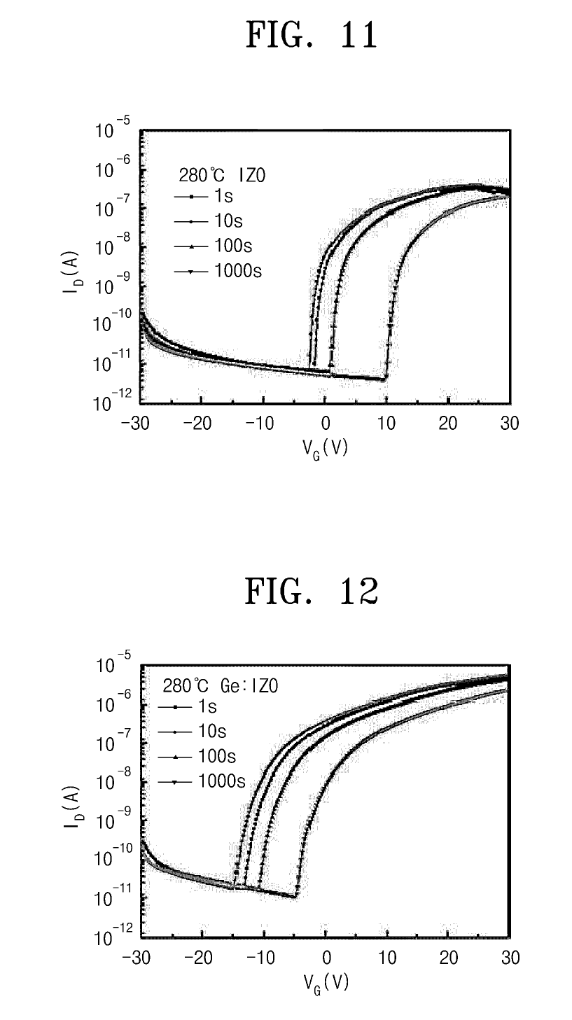

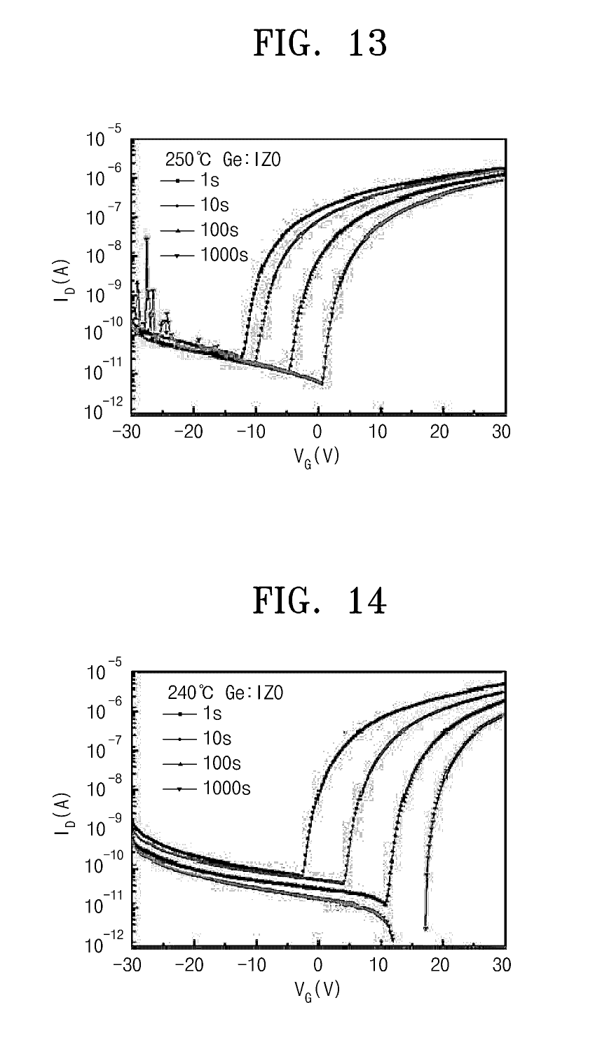

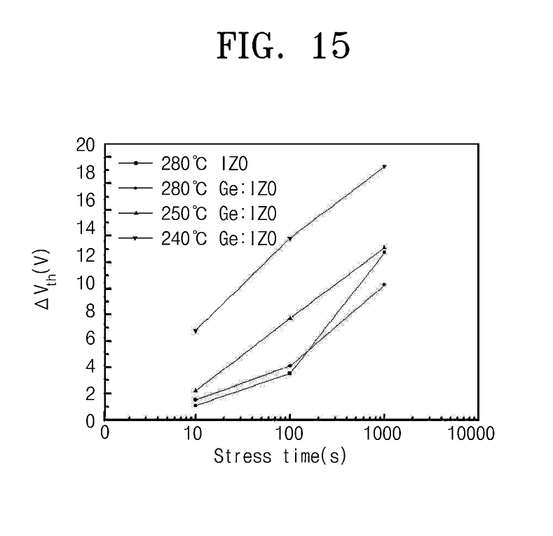

FIG. 11 is a graph showing PBS test results of an InZnO thin film transistor of Comparative Example, which is heat-treated at a temperature of about 280° C.; FIG. 12 is a graph showing PBS test results of a germanium-doped InZnO thin film transistor of Embodiment, which is heat-treated at a temperature of about 280° C.; FIG. 13 is a graph showing PBS test results of a germanium-doped InZnO thin film transistor of Embodiment 3, which is heat-treated at a temperature of about 250; and FIG. 14 is a graph showing PBS test results of a germanium-doped InZnO thin film transistor of Embodiment 4, which is heat-treated at a temperature of about 240° C.

In the PBS tests, a VG and a VD were set to 20 V and 10 V, respectively, variations of threshold voltage (Δ Vₜₕ) were measured by checking transfer characteristic of the elements after about 1 second, about 10 seconds, about 100 seconds, and about 1,000 seconds

The variations of threshold voltage (Δ Vₜₕ) measured after about 1,000 seconds with respect to thin film transistors according to Comparative Example and Embodiments 1, 3 and 4 are shown in Table 2 below.

TABLE 2

| | Post-heat treating temperature and | |
|---|---|---|
| | thin film | ΔVₜₕ (V) |
| Comparative Example | 280° C. InZnO | 12.7 |
| Embodiment 1 | 280° C. Ge:InZnO | 10.2 |
| Embodiment 3 | 250° C. Ge:InZnO | 13.1 |
| Embodiment 4 | 240° C. Ge:InZnO | 19.3 |

Also, FIG. 15 is a graph showing variations of threshold voltage according to time in an InZnO thin film transistor according to Comparative Example, which is heat-treated at a temperature of about 280° C., and Ge:InZnO thin film transistors according to Embodiments 1, 3 and 4, which are heat-treated at temperatures of about 280° C., about 260° C. and about 240° C.

Referring to FIGS. 10 to 14, and Table 2, when elements are fabricated under the same condition, it may confirmed that the elements according to Embodiments of the present invention including a thin film which is doped with germanium, have variations of threshold voltage (Δ Vₜₕ) that are smaller than that of the element according to Comparative Example including a thin film which is not doped with germanium, so that the elements according to Embodiments have excellent stability compared to the element according to Comparative Example.

Also, it may be confirmed that the InZnO thin film transistor fabricated according to Comparative Example has the similar variation of threshold voltage (Δ Vₜₕ) to the Ge:InZnO thin film transistor post-heat treated at a temperature of about 250° C. according to Embodiment 3 of the present invention.

Therefore, when germanium is doped into a thin film as in Embodiments of the present invention, it may be confirmed that a heat treatment temperature of an element may be lowered without largely reducing performance of the element.

A method for forming a metal compound thin film by doping germanium, and a method for fabricating an oxide thin film transistor using the same have been described above.

It has been confirmed that according to Embodiments of the present invention, when germanium is doped into a metal compound thin film, electrical characteristics and stability of an oxide thin film and a thin film transistor including the same may be improved.

Also, according to Embodiments of the present invention, when an oxide thin film is formed by using a metal compound solution in which germanium is dissolved, heat treatment temperature may be lowered to prevent deformation of a plastic substrate.

According to embodiments of the present invention, electrical characteristics and stability of an oxide thin film and a thin film transistor including the same may be improved.

According to embodiments of the present invention, when an oxide thin film is formed through a solution process, heat treatment temperature may be lowered to prevent deformation of a substrate formed of low heat resistivity glass or plastic.

The above-disclosed subject matter is to be considered illustrative, and not restrictive, and the appended claims are intended to cover all such modifications, enhancements, and other embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. A method for forming an oxide thin film, the method comprising:
applying a metal compound solution onto a substrate; and
heat-treating the substrate,
wherein the metal compound solution is prepared by dissolving an indium compound, a zinc compound, and a germanium compound in a solvent.

2. The method of claim 1, wherein a molar ratio between the indium compound and the zinc compound is in a range of about 1:5 to about 5:1.

3. The method of claim 2, wherein a molar ratio between the indium compound and the zinc compound is about 5:1.

4. The method of claim 1, wherein the molar percentage of the germanium compound with respect to the zinc compound and the germanium compound is greater than about 0% and is about 15% or less.

5. The method of claim 4, wherein the molar percentage of the germanium compound with respect to the indium compound, the zinc compound, and the germanium compound is about 4.3%.

6. The method of claim 1, wherein the metal compound solution comprises at least one of a nitric acid, an acetic acid, a hydrochloric acid, a sulfuric acid, and monoethanolamine which are added therein.

7. The method of claim 6, wherein the metal compound solution comprises the nitric acid added therein.

8. The method of claim 7, wherein a molar ratio between the solvent and the nitric acid is about 20:1.

9. The method of claim 1, wherein the heat-treating of the substrate comprises heat-treating the substrate in a temperature range of about 240° C. to about 280° C.

10. The method of claim 9, wherein the heat-treating of the substrate further comprising heat-treating the substrate in a temperature range of about 100° C. to about 150° C. prior to heat-treating the substrate in a temperature range of about 240° C. to about 280° C.

11. The method of claim 10, wherein the heat-treating of the substrate in the temperature range of about 100° C. to about 150° C. comprises heat-treating the substrate at a temperature of about 135° C.

12. The method of claim 11, wherein the heat-treating of the substrate at the temperature of about 135° C. comprises heat-treating the substrate at a temperature of about 135° C. for about 5 minutes; and the heat-treating of the substrate in the temperature range of about 240° C. to about 280° C. comprises heat-treating the substrate in a temperature range of about 240° C. to about 280° C. for about 4 hours.

13. A method for fabricating an oxide thin film transistor, the method comprising:
forming a gate and an insulation layer on a substrate;
applying a metal compound solution onto the insulation layer;
heat-treating the substrate to form an oxide thin film from the metal compound solution; and
forming a source and a drain on the oxide thin film,
wherein the metal compound solution is prepared by dissolving an indium compound, a zinc compound, and a germanium compound in a solvent.

14. The method of claim 13, wherein a molar ratio between the indium compound and the zinc compound is in a range of about 1:5 to about 5:1.

15. The method of claim 13, wherein a molar percentage of the germanium compound with respect to the zinc compound and the germanium compound is greater than about 0% and is about 15% or less.

16. The method of claim 13, wherein the metal compound solution comprises at least one of a nitric acid, an acetic acid, a hydrochloric acid, a sulfuric acid, and monoethanolamine which are added therein.

17. The method of claim 16, wherein the metal compound solution comprises the nitric acid added therein.

18. The method of claim 13, wherein the heat-treating of the substrate to form the oxide thin film from the metal compound solution comprises:
pre-heat treating the substrate in a temperature range of about 100° C. to about 150° C.; and
post-heat treating the substrate in a temperature range of about 240° C. to about 280° C.
